(19) United States
(12) Patent Application Publication
(10) Pub. No.: US 2025/0253164 A1
(43) Pub. Date: Aug. 7, 2025

(54) TUBE FOR SEMICONDUCTOR MANUFACTURING EQUIPMENT

(71) Applicant: AGC Inc., Tokyo (JP)

(72) Inventors: Yuto NAKAGAWA, Tokyo (JP); Shinji WADA, Tokyo (JP); Sadao KANETOKU, Tokyo (JP); Ryuta YANAGAWA, Tokyo (JP)

(73) Assignee: AGC Inc., Tokyo (JP)

(21) Appl. No.: 19/189,417

(22) Filed: Apr. 25, 2025

Related U.S. Application Data
(63) Continuation of application No. PCT/JP2023/046905, filed on Dec. 27, 2023.

(30) Foreign Application Priority Data
Dec. 28, 2022 (JP) 2022-212110

(51) Int. Cl. H01L 21/67; C08F 14/26

(52) U.S. Cl. CPC H01L 21/67017; C08F 14/26

(57) ABSTRACT

Provided is a tube for semiconductor manufacturing equipment, which is excellent in joint connectivity and cleanability. The tube according to the present invention is a tube for semiconductor manufacturing equipment, containing a fluorinated polymer, wherein a permanent creep strain of the fluorinated polymer is 4.5% or more, a creep rate of the fluorinated polymer a determined by a tensile creep test is 2.60% or lower, a bending elastic modulus of the fluorinated polymer is 1100 MPa or lower, and a water contact angle of the fluorinated polymer is 112.0 degrees or smaller.

### TECHNICAL FIELD

The present invention relates to a tube for semiconductor manufacturing equipment.

### BACKGROUND ART

Fluorinated polymers have been applied in various fields because of their excellent heat resistance, chemical resistance, mechanical properties, electrical properties, surface properties and the like, and have been used as forming materials to form pipes for transportation of various fluids, joint members (fittings) for pipes, storage containers, members for pumps and filter housings, and the like in manufacturing equipment of electronic components such as semiconductor elements, chemicals and pharmaceuticals.

For example, Patent Document 1 discloses a PFA formed product formed from a copolymer (PFA) of tetrafluoroethylene (TFE) and a perfluoro (alkyl vinyl ether) (PAVE) with a PAVE content of 1 to 10 mol %, wherein the formed product has predetermined values for its flex life, zero share viscosity and heating weight loss.

### PRIOR ART DOCUMENTS

### Patent Documents

Patent Document 1: WO 2019/003265

### DISCLOSURE OF INVENTION

### Technical Problem

In the case where fluorinated polymers are used as constituent materials of tubes for semiconductor manufacturing equipment, not only excellent characteristic properties such as chemical resistance, mechanical strength and electrical insulation property, but also excellent properties of allowing easy connection of the tubes to joints in semiconductor manufacturing equipment to form connection parts therebetween and, at the time of transferring a liquid or gas through hollow portions of the tubes after the connection, being unlikely to cause leakage of the liquid or gas from the connection parts (hereinafter both referred to together as “joint connectivity”), are required.

Furthermore, excellent cleanability is required to suppress contamination of semiconductor manufacturing equipment and wafers with impurities.

The present inventors have assessed a tube for semiconductor manufacturing equipment, formed from the fluorinated copolymer as disclosed in Patent Document 1, and as a result have found that the tube is still in need of improvements in joint connectivity and cleanability.

It is accordingly an object of the present invention to provide a tube for semiconductor manufacturing equipment, which is excellent in joint connectivity and cleanability.

### Solution to Problem

As a result of extensive studies made on the above object, the present inventors have found that a tube for semiconductor manufacturing equipment containing a fluorinated polymer, when a formed product of the fluorinated polymer satisfies a predetermined requirement A, can attain excellent joint connectivity and excellent cleanability, and then have accomplished the present invention.

That is, the present inventors have found that the above object can be achieved by the following configurations.

[1] A tube for semiconductor manufacturing equipment, comprising a fluorinated polymer, wherein the fluorinated polymer satisfies the following requirement A:
(requirement A)
a permanent creep strain of the fluorinated polymer is 4.5% or more;
a creep rate of the fluorinated polymer as determined by a tensile creep test is 2.60% or lower;
a bending elastic modulus of the fluorinated polymer is 1100 MPa or lower; and
a water contact angle of the fluorinated polymer is 112.0 degrees or smaller.

[2] The tube according to [1], wherein the fluorinated polymer comprises units based on tetrafluoroethylene.

[3] The tube according to [2], wherein the fluorinated polymer further comprises units based on at least one monomer selected from the group consisting of ethylene, propylene, a fluoroalkyl ethylene and a perfluoro (alkyl vinyl ether).

[4] The tube according to [2] or [3], wherein the fluorinated polymer further comprises units based on at least one monomer selected from the group consisting of ethylene and a fluoroalkyl ethylene.

[5] The tube according to any one of [1] to [4], wherein the tube is a tube for transporting a chemical liquid for semiconductors in semiconductor manufacturing equipment or a tube for transporting a gas in semiconductor manufacturing equipment.

[6] The tube according to any one of [1] to [4], wherein the water contact angle is 90 degrees or larger.

### Advantageous Effects of Invention

According to the present invention, it is possible to provide a tube for semiconductor manufacturing equipment, which is excellent in joint connectivity and cleanability.

### DESCRIPTION OF EMBODIMENTS

The meanings of terms in the present specification are as follows.

A numerical range expressed using “to” means a range including numerical values described before and after “to” as the lower and upper limits.

A “unit” is a generic term for an atomic group derived from a single monomer molecule, which is directly formed by polymerization reaction of the monomer, and an atomic group obtained by chemical conversion of a part of the aforementioned atomic group. The content (mol %) of each type of units to all units in a polymer is determined by nuclear magnetic resonance spectroscopic analysis of the polymer, and can also be determined from the amounts of charge of components used for production of the polymer.

In the following, units derived from each individual monomer are occasionally represented with the name of the monomer followed by “units”. For example, “TFE units” mean units based on tetrafluoroethylene, and “E units” means units based on ethylene.

### [Tube for Semiconductor Manufacturing Equipment]

The tube for semiconductor manufacturing equipment according to the present invention (hereinafter also simply referred to as the present tube) is a tube for semiconductor manufacturing equipment, containing a fluorinated polymer, wherein the fluorinated polymer satisfies the following requirement A.

### (Requirement A)

The permanent creep strain of the fluorinated polymer is 4.5% or more;
the creep rate of the fluorinated polymer as determined by a tensile creep test is 2.60% or lower;
the bending elastic modulus of the fluorinated polymer is 1100 MPa or lower; and
the water contact angle of the fluorinated polymer is 112.0 degrees or smaller.

By containing the fluorinated polymer that satisfies the requirement A, the tube can attain excellent joint connectivity and excellent cleanability. The reason for this is not necessarily clearly understood, but is considered as follows.

It is presumed that, when the permanent creep strain is 4.5% or more, the time from when the tube is radially expanded by flaring for connection to a joint until when the tube is returned to its original diameter becomes long so that the tube is improved in workability of connection to the joint.

It is presumed that, when the creep rate is 2.60% or lower, creep deformation of the tube after connection to a joint is less likely to occur, and thus, leakage from the connection part between the tube and the joint is less likely to occur.

It is presumed that, when the bending elastic modulus is 1100 MPa or lower, the tube is easier to flare and thus is easier to connect to a joint.

It is further presumed that, when the water contact angle is 112.0 degrees or smaller, the wettability of the tube to cleaning water becomes high so that the tube is improved in cleanability.

### [Fluorinated Polymer]

The configuration of the fluorinated polymer will be first described below, and the physical properties, including the requirement A, of the fluorinated polymer will be next described below.

The fluorinated polymer is a polymer having units containing fluorine atoms.

In view of the heat resistance of the tube, the fluorinated polymer preferably has units based on tetrafluoroethylene (hereinafter also referred to as “TFE”).

The fluorinated polymer preferably also has units based on a monomer copolymerizable with TFE units (hereinafter also referred to as “the other monomer”).

As examples of the other monomer, ethylene, propylene, a perfluoro (alkyl vinyl ether) (hereinafter also referred to as “PAVE”), a fluoroalkyl ethylene (hereinafter also referred to as “FAE”) and hexafluoropropylene may be mentioned

Specific examples of PAVE include CF₂═CFOCF₃ (hereinafter also referred to as “PMVE”), CF₂═CFOCF₂CF₃, CF₂═CFOCF₂CF₂CF₃ (hereinafter also referred to as “PPVE”), CF₂═CFOCF₂CF₂CF₂CF₃ and CF₂═CFO(CF₂)₈F. Preferred is PMVE or PPVE.

Specific examples of FAE include CH₂═CH(CF₂)₂F (hereinafter also referred to as “PFEE”), CH₂═CH(CF₂)₃F, CH₂═CH(CF₂)₄F (hereinafter also referred to as “PFBE”), CH₂═CF(CF₂)₃H and CH₂═CF(CF₂)₄H. Preferred is PFEE or PFBE.

As examples of the other monomer, vinyl chloride, vinylidene chloride and vinyl fluoride may also be mentioned.

Further, a monomer with an oxygen-containing polar group may also be mentioned as an example of the other monomer. The oxygen-containing polar group is preferably an acid anhydride residue, a hydroxy group, a carbonyl-containing group, an acetal group or an oxycycloalkane group, and is more preferably an acid anhydride residue. As the monomer with an acid anhydride residue, a monomer with a cyclic acid anhydride residue is preferred. More preferred is itaconic anhydride, citraconic anhydride, 5-norbornene-2,3-dicarboxylic anhydride or maleic anhydride.

Among others, the fluorinated polymer preferably has, as the other monomer units, units based on at least one monomer selected from the group consisting of ethylene, propylene, a fluoroalkyl ethylene and a perfluoro (alkyl vinyl ether), more preferably units based on at least one monomer selected from the group consisting of ethylene and a fluoroalkyl ethylene. The other monomer units are still more preferably units based on at least one monomer selected from the group consisting of ethylene and a fluoroalkyl ethylene.

In the case where the fluorinated polymer has TFE units, the content of the TFE units to all the units in the fluorinated polymer is preferably 40 to 65 mol %, more preferably 45 to 60 mol %, still more preferably 50 to 60 mol %, with a view to obtaining higher heat resistance of the tube.

In the case where the fluorinated polymer has TFE units and the other monomer units, the content of the TFE units to the sum of the TFE units and the other monomer units is preferably 40 to 65 mol %, more preferably 45 to 60 mol %, still more preferably 50 to 60 mol %.

Furthermore, the content of the other monomer units to the sum of the TFE units and the other monomer units is preferably 35 to 60 mol %, more preferably 40 to 55 mol %, still more preferably 40 to 50 mol %.

A preferred embodiment of the fluorinated polymer is a polymer having TFE units, ethylene units (hereinafter also referred to as “E units”) and FAE units. A polymer consisting of TFE units, E units and FAE units is more preferred.

In this case, the content of the TFE units to the sum of the TFE units, the E units and the FAE units is preferably 40 to 64.9 mol %, more preferably 45 to 60 mol %, still more preferably 50 to 60 mol %.

The content of the E units to the sum of the TFE units, the E units and the FAE units is preferably 35.0 to 59.9 mol %, more preferably 35.5 to 54.5 mol %, still more preferably 36.0 to 49.0 mol %.

Furthermore, the content of the FAE units to the sum of the TFE units, the E units and the FAE units is preferably 0.1 to 5.0 mol %, more preferably 0.5 to 4.5 mol %, still more preferably 1.0 to 4.0 mol %.

The content of the fluorinated polymer to the total mass of the present tube is preferably 50 to 100 mass %, more preferably 75 to 100 mass %, still more preferably 90 to 100 mass %, to obtain a higher effect of the present invention.

The fluorinated polymer may be a combination of two or more types.

### <Physical Properties>

The physical properties, including the requirement A, of the fluorinated polymer will be described in detail below.

### (Permanent Creep Strain)

The permanent creep strain of the fluorinated polymer in the present tube is 4.5% or more.

The permanent creep strain is a value determined as, when a compression creep test is performed in accordance with ASTM D621 in which a test specimen produced by forming the fluorinated polymer is subjected to compression deformation for 24 hours at a test temperature of 300° C. and a test pressure of 140 kgf/cm² and then left standing still for 24 hours, the rate (unit: %) of dimensional change of the test specimen before and after the test relative to the dimension of the test specimen before the test. The detailed measurement conditions of the permanent creep strain will be described in Examples below.

The permanent creep strain of the fluorinated polymer is preferably 4.7% or more, more preferably 5.0% or more, with a view to achieving higher joint connectivity. Furthermore, the permanent creep strain of the fluorinated polymer is preferably 10.0% or less, more preferably 8.5% or less, with a view to achieving higher resistance to liquid leakage after connection to a joint.

The permanent creep strain of the fluorinated polymer can be adjusted by increasing the molecular weight of the fluorinated polymer, changing the crystallinity degree of the fluorinated polymer, or the like. By adjusting the molecular weight, the entanglement of polymer chains can be changed to adjust the permanent creep strain. By varying the constituent monomer ratio, the crystallinity degree can be changed to adjust the permanent creep strain.

### (Creep Rate by Tensile Creep Test)

The creep rate as determined by a tensile creep test (hereinafter also simply referred to as “creep rate”) of the fluorinated polymer in the present tube is 2.60% or lower.

The creep rate is a value determined as, when a test specimen produced by forming the fluorinated polymer is subjected to a tensile creep test in accordance with ASTM D674 under the conditions of a test temperature of 23° C.±3° C., a stress of 70 kgf/cm² and a test time of 150 hours, the rate (unit: %) of change of the chuck distance before and after the test relative to the chuck distance before the test. The detailed measurement conditions of the creep rate will be described in Examples below.

The creep rate of the fluorinated polymer is preferably 2.10% or lower, more preferably 2.00% or lower, with a view to achieving higher joint connectivity.

Furthermore, the creep rate of the fluorinated polymer is preferably 1.00% or higher, more preferably 1.20% or higher.

The creep rate of the fluorinated polymer can be adjusted by, for example, adjusting the MFR of the fluorinated polymer to within the later-described range (in particular, 1 to 20 g/10 min).

### (Bending Elastic Modulus)

The bending elastic modulus of the fluorinated polymer in the present tube is 1100 MPa or lower.

The bending elastic modulus is a value (unit: MPa) determined from a stress-strain curve when a test specimen produced by forming the fluorinated polymer is subjected to a bending test at 23° C. in accordance with ASTM D790 to measure the stress and strain acting on the test specimen. The detained measurement conditions of the bending elastic modulus will be described in Examples below.

The bending elastic modulus of the fluorinated polymer is preferably 1080 MPa or lower, more preferably 800 MPa or lower, with a view to achieving higher joint connectivity.

Furthermore, the bending elastic modulus of the fluorinated polymer is preferably 300 MPa or higher, more preferably 400 MPa or higher, with a view to achieving higher pressure resistance.

The bending elastic modulus of the fluorinated polymer can be adjusted by, for example, adjusting the crystallinity degree of the fluorinated polymer, adjusting the MFR of the fluorinated polymer, or the like.

Here, the crystallinity degree increases with decrease, and decreases with increase, in the content of units with a carbon number of 3 or more in the fluorinated polymer. For example, by using the fluorinated polymer with a crystallinity degree of 30% or higher, the bending elastic modulus of the fluorinated polymer can be adjusted to within the above-specified range. The bending elastic modulus of the fluorinated polymer can also be adjusted to within the above-specified range by adjusting the MFR of the fluorinated polymer to within the later-described range (in particular, 1 to 30 g/10 min).

The crystallinity degree is determined as, when a test specimen produced by forming the fluorinated polymer is measured for its fusion heat (J/g) with the use of a differential scanning calorimeter, the ratio of the measured fusion heat to the fusion heat (J/g) of a perfect crystal of the measurement target material (100×measured fusion heat/fusion heat of perfect crystal, unit: %).

### (Water Contact Angle)

The water contact angle of the fluorinated polymer in the present tube is 112.0 degrees or smaller.

The water contact angle is an angle of contact (unit: degree), as determined by the 0/2 method, with respect to drops of pure water dropped on and adhered to a surface of a test sample obtained by forming the fluorinated polymer. The detailed measurement conditions of the water contact angle will be described in Examples below.

The water contact angle of the fluorinated polymer is preferably 110.0 degrees or smaller, more preferably 105 degrees or smaller, with a view to achieving higher cleanability.

Furthermore, the water contact angle of the fluorinated polymer is preferably 90 degrees or larger, more preferably 100 degrees or larger, with a view to achieving more suppression of the adhesion of foreign matter.

The water contact angle of the fluorinated polymer can be adjusted by appropriately increasing or decreasing the fluorine content of the fluorinated polymer.

### (Melting Point)

The melting point of the fluorinated polymer is preferably 200° C. or higher, more preferably 215° C. or higher, still more preferably 230° C. or higher, with a view to achieving higher heat resistance.

The upper limit of the melting point of the fluorinated polymer is preferably 290° C. or lower, more preferably 280° C. or lower, still more preferably 270° C. or lower, with a view to achieving higher formability of the fluorinated polymer.

As a method for adjusting the melting point of the fluorinated polymer to within the above-mentioned range, there may be mentioned lowering of the polymerization temperature during production of the fluorinated polymer, adjusting of the content of units with a carbon number of 3 or more in the fluorinated polymer, and the like.

The melting point of the fluorinated polymer is a temperature corresponding to an endothermic peak during a process of heating the fluorinated polymer to raise the temperature of the fluorinated polymer to 300° C. at 10° C./min in an air atmosphere with the use of a differential scanning calorimeter.

### (Melt Flow Rate)

The melt flow rate (also referred to as “MFR”) of the fluorinated polymer is preferably 1 to 100 g/10 min, more preferably 1 to 50 g/10 min, still more preferably 1 to 30 g/10 min, particularly preferably 1 to 20 g/10 min, with a view to achieving higher formability of the fluorinated polymer and higher mechanical strength and wear resistance of the formed product.

The MFR of the fluorinated polymer can be adjusted to within the above range by adjusting the molecular weight of the fluorinated polymer. The larger the molecular weight of the fluorinated polymer, the lower the MFR.

The MFR of a fluorinated polymer is determined as a mass of the fluorinated polymer flowing out from an orifice with a diameter of 2 mm and a length of 8 mm for 10 minutes, as measured under the conditions of a temperature of 297° C. and a load of 49N in accordance with ASTM D3159.

### <Production Method>

The fluorinated polymer can be produced by polymerization of the above-mentioned monomers according to a known process such as bulk polymerization, solution polymerization, suspension polymerization, emulsion polymerization or the like. Solution polymerization is preferred as a method for producing the fluorinated polymer.

In the production of the fluorinated polymer, a polymerization initiator, a polymerization medium, a chain transfer agent and the like can be used in addition to the above-mentioned monomers.

The polymerization initiator is preferably a radial polymerization initiator having a 10-hour half-life temperature of 0 to 100° C., more preferably a radical polymerization initiator having a 10-hour half-life temperature of 20 to 90° C. Specific examples of the polymerization initiator include various polymerization initiators disclosed in WO 2013/015202.

The polymerization initiator can be one type alone or a combination of two types or more.

The amount of the polymerization initiator used is preferably 0.01 to 0.9 parts by mass, more preferably 0.05 to 0.5 parts by mass, per 100 parts by mass of the monomers used.

The polymerization medium can be a perfluorocarbon, a hydrofluorocarbon, a hydrofluoroether, or the like. Specific examples of the polymerization medium include polymerization mediums disclosed in WO 2013/015202.

The polymerization medium can be one type alone or a combination of two or more types.

The amount of the polymerization medium used is preferably 5 times or more, more preferably 7 times or more, in terms of mass ratio relative to the amount of the monomers used. Further, the amount of the polymerization medium used is preferably 20 times or less, more preferably 17 times or less.

From the viewpoint of obtaining a high chain transfer constant and achieving a smaller amount of use, preferable examples of the chain transfer agent include: alcohols such as methanol, ethanol, 2,2,2-trifluoroethanol, 2,2,3,3-tetrafluoropropanol, 1, 1,1,3,3,3-hexafluoroisopropanol and 2,2,3,3,3-pentafluoropropanol; hydrocarbons such as n-pentane, n-hexane and cyclohexane; hydrofluorocarbons such as CF₂H₂; ketones such as acetone; mercaptans such as methyl mercaptan; esters such as methyl acetate and ethyl acetate; and ethers such as diethyl ether and methyl ethyl ether.

Among others, preferred is at least one type selected from the group consisting of alcohols, hydrocarbons and hydrofluorocarbons from the viewpoint of obtaining a higher chain transfer constant and achieving high stability of the terminal groups of the fluorinated polymer. At least one type selected from the group consisting of alcohols and hydrocarbons is more preferred. Any of alcohols is further more preferred. Of the alcohols, methanol or ethanol is preferred. In particular, methanol is more preferred because of its reactivity and availability.

The chain transfer agent can be a combination of two or more types.

The amount of the chain transfer agent used is preferably 0.001 times or more, more preferably 0.005 times or more, in terms of mass ratio relative to the amount of monomers used. Further, the amount of the chain transfer agent used is preferably 5 times or less, more preferably 4 times or less.

The polymerization temperature is preferably 15 to 100° C., more preferably 20 to 90° C., still more preferably 25 to 80° C. When the polymerization temperature is higher than or equal to the above-mentioned lower limit, good polymerizability is obtained. When the polymerization temperature is lower than or equal to the above-mentioned upper limit, the melting point of the fluorinated polymer can be improved.

The polymerization pressure is preferably 0.5 to 3.0 MPa, more preferably 0.9 to 2.5 MPa.

The polymerization time is preferably 1 to 12 hours.

### [Additional Component]

The present tube may contain a component other than the above-mentioned fluorinated polymer (hereinafter also referred to as “additional component”) within the range that exerts a sufficient effect of the present invention.

Specific examples of the additional component include a thermal stabilizer, an antioxidant, a polymer other than the fluorinated polymer, a coloring agent, an ultraviolet absorber, a filler, a cross-linking agent and a cross-linking aid.

In the case where the present tube contains an additional component, the content of the additional component to the total mass of the present tube is preferably 99 mass % or less, more preferably 50 mass % or less, still more preferably 10 mass % or less.

The additional component may be a combination of two or more types.

### [Shape of Tube]

The present tube is a tubular member with both ends open.

The thickness of the present tube is preferably 4 mm or smaller, more preferably 3 mm or smaller, still more preferably 2 mm or smaller, with a view to obtaining a more effect of buckling resistance. The thickness of the present tube is preferably 0.1 mm or larger, more preferably 0.5 mm or larger, with a view to achieving higher buckling resistance. The thickness of a tube is a value obtained by dividing a difference between the outer and inner diameters of the tube in half.

Here, buckling resistance refers to the property of, during installation in semiconductor equipment, incurring no large bending and being less likely to be buckled (hereinafter simply referred to as “buckling resistance”).

The outer diameter of the present tube is preferably 1 to 55 mm, more preferably 1 to 40 mm, still more preferably 1 to 35 mm.

The inner diameter of the present tube is smaller than the outer diameter of the present tube, and is preferably 0.5 to 50 mm, more preferably 0.5 to 40 m, still more preferably 0.5 to 35 mm.

The shape of the open ends of the tube and the shape of a cross section of the tube as taken perpendicular to a longitudinal direction of the tube can be, for example, a circular shape, an oval shape or a polygonal shape. A circular shape or an oval shape is preferred. More preferred is a circular shape.

### [Method for Producing Tube]

The present tube can be produced by melt-forming the fluorinated polymer which is provided in powdery form, granular form, pellet form or other form.

As a method of melt-forming, a known process such as extrusion forming, injection forming, blow forming, press forming or rotary forming may be mentioned.

The melt-forming temperature is preferably a temperature higher than the melting temperature of the fluorinated polymer and 50 to 200° C. lower (more preferably 50 to 150° C. lower) than the thermal decomposition temperature of the fluorinated polymer.

The present tube can alternatively be produced by melt-forming a composition containing the fluorinated polymer and the above-mentioned additional component.

The content of the fluorinated polymer in the composition to the total mass of the composition is preferably 50 mass % or more and less than 100 mass %, more preferably 70 mass % or more and less than 100 mass %, still more preferably 90 mass % or more and less than 100 mass %.

The content of the additional component in the composition to the total mass of the composition is preferably more than 0 mass % and 50 mass % or less, more preferably more than 0 mass % and 30 mass % or less, still more preferably more than 0 mass % and 10 mass % or less.

The composition can be obtained by melt-mixing the fluorinated polymer with the additional component used as necessary according to a known process.

As the method for producing the present tube, extrusion forming is preferred in which the tube can be produced with a constant cross-sectional shape.

As an example of an extruder used for extrusion forming, an extrusion forming machine with a hopper, a screw, a cylinder, a die and an adapter (a joint part between the screw and the die) may be mentioned.

The extruder may be a single-screw extruder or a twin-screw extruder. A vent hole may be provided in the cylinder and kept open to remove a volatile component generated from the fluorinated polymer.

In the extrusion forming using the extruder, the cylinder temperature is preferably 150 to 400° C., more preferably 180 to 390° C. Furthermore, the die temperature is preferably 200 to 380° C., more preferably 210 to 370° C.

### [Applications]

The present tube is a tube for semiconductor manufacturing equipment. The present tube has excellent joint connectivity so as to be easily connected to joints and be less likely to cause leakage after the connection, and thus is particularly suitable for use in semiconductor manufacturing equipment as a tube for transporting a chemical liquid for semiconductors in semiconductor manufacturing equipment or a tube for transporting a gas in semiconductor manufacturing equipment.

The above-mentioned chemical liquid for semiconductors is a chemical liquid used in a process of manufacturing semiconductors. Specific examples of the chemical liquid include an etching liquid, a liquid developer, a rinsing liquid and a cleaning liquid.

The above-mentioned gas is a gas fed into semiconductor manufacturing equipment for use in a process of manufacturing semiconductors. Specific examples of the gas include a raw material gas as a film forming material for semiconductors, and a process gas and inert gas for use in each of steps of etching, development, rinsing, cleaning or the like.

The present tube is also suitably usable as a tube for transporting a liquid or gas in the fields, where the reduction of pollution and contamination from equipment is required, such as production of pharmaceuticals, production of medical devices, analytical instruments and food, and the like.

### EXAMPLES

Now, the present invention will be described in further detail below with reference to Examples. Ex. 1 and Ex. 2 correspond to Examples of the present invention, and Ex. 3 to Ex. 5 correspond to Comparative Examples. It should however be understood that the present invention is by no means restricted to these working examples.

### <Measurement of Composition of Fluorinated Polymer>

The content (mol %) of each type of units in a fluorinated polymer was determined by ¹⁹F-Nuclear Magnetic Resonance (NMR) measurement. However, the content of ethylene (E) units in a fluorinated polymer was measured by ¹H- and ¹³C-NMR measurements.

### <Measurement of Melting Point>

The melting point (° C.) of a fluorinated polymer was determined from a endothermic peak as observed by heating the fluorinated polymer to raise the temperature of the fluorinated polymer to 300° C. at 10° C./min in an air atmosphere with the use of a differential scanning calorimeter (model “DSC7020”, manufactured by Hitachi High-Tech Corporation).

### <Measurement of MFR>

Using a melt indexer (manufactured by Techno Seven Co., Ltd.), the mass (g) of a fluorinated polymer flowing out from an orifice with a diameter of 2 mm and a length of 8 mm for 10 minutes under the conditions of a temperature of 297° C. and a load of 49 N was measured in accordance with ASTM D3159 and taken as the MFR (g/10 min).

### [Ex. 1]

### <Synthesis of Fluorinated Polymer 1>

An autoclave of stainless steel having an internal volume of 215 liters and equipped with an agitator was degassed and then charged with 208.6 kg of CF₃ (CF₂)₅H, 1.9 kg of methanol and 0.95 kg of perfluorobutyl ethylene (PFBE). The resulting mixture was raised in temperature to 66° C. while stirring, and a mixed gas of tetrafluoroethylene (TFE)/ethylene (E)=83/17 (mol %) was introduced into the autoclave until the pressure inside the autoclave reached 1.5 MPaG.

Subsequently, 524 g of a CF₃ (CF₂)₅H solution of tert-butyl peroxypivalate (concentration: 1 mass %) was introduced into the autoclave to initiate polymerization. During the polymerization, a mixed gas of TFE/E=54/46 (mol %) and PFBE in an amount equivalent to 1.4 mol % relative to the mixed gas were continuously introduced into the autoclave such that the pressure inside the autoclave was kept at 1.5 MPaG.

At the time when: 10 hours elapsed from the initiation of the polymerization; and the amount of introduction of the mixed gas reached 13.5 kg, the inside of the autoclave was cooled to 23° C. to stop the polymerization. A part of the remaining mixed gas was purged, thereby obtaining a slurry 1.

Then, 120 kg of the obtained slurry 1 was stored in a storage tank, and the obtained slurry 1 was put into a 220-L granulation tank charged with 77 kg of water. The resulting mixture was subjected to granulation with distillation removal of the solvent by raising the temperature to 105° C. while stirring. The thus-obtained powdery granulation product was collected as a fluorinated polymer 1.

The fluorinated polymer 1 had a composition of TFE units/E units/PFBE units of 53.4/44.9/1.5 in molar ratio.

Further, the melting point of the fluorinated polymer 1 was 259° C., and the MFR of the fluorinated polymer 1 was 6.7 g/10 min.

### <Production of Pellets 1>

The above-obtained fluorinated polymer 1 was melt-kneaded by a single-screw extruder with an opening diameter of 30 mm, and the resulting strand-shaped formed product was cut by a pelletizer to obtain pellets 1 of the fluorinated polymer 1. During the melt-kneading of the fluorinated polymer 1, the cylinder temperature was set to 260 to 320° C., and the die temperature was set to 320° C.

### <Production of Tube 1>

A tube production device was provided, including: a single-screw extruder (manufactured by Tanabe Plastics Machinery Co., Ltd.) having an opening diameter of 30 mm to produce a tube from pellets of a fluorinated polymer; a take-off machine for taking off the tube; and a winder for winding the tube.

The above-obtained pellets 1 of the fluorinated polymer 1 were put into and melt-kneaded in the single-screw extruder of the tube production device, and the melt-kneaded material was extruded into a tubular shape from the single-screw extruder whereby a tube 1 having a cross-sectional shape with an inner diameter of 11.1 mm and an outer diameter of 12.7 mm was obtained.

The compression ratio of the screw in the single-screw extruder was 3, and the ratio of L (effective screw length)/D (screw diameter) was 24. In the single-screw extruder, the cylinder temperature was set to 250 to 290° C., and the die temperature was set to 290° C. Further, the take-off speed of the tube 1 was adjusted to 1 m/min.

### [Ex. 2]

### <Synthesis of Fluorinated Polymer 2>

A polymerization tank having an internal volume of 260 liters and equipped with an agitator was degassed. Then, the polymerization tank was charged with 54.6 kg of deionized water, 173.3 kg of 1-hydrotridecafluorohexane and 19.3 kg of methanol and further charged with 31.4 kg of tetrafluoroethylene (TFE), 0.86 kg of ethylene (E) and 2.12 kg of PFBE. The resulting mixture in the polymerization tank was raised in temperature to 66° C. (polymerization temperature) while stirring, and 1.54 L of a 1-hydrotridecafluorohexane solution containing 2.0 mass % of tert-butyl peroxypivalate was introduced into the polymerization tank to initiate polymerization.

During the polymerization, a mixed monomer gas of TFE/E=60/40 (molar ratio) was continuously charged such that the pressure inside the polymerization tank was kept constant, and PFBE in an amount equivalent to 3.3 mol % relative to the mixed monomer gas of TFE/E was continuously charged. The pressure inside the polymerization tank during the polymerization was kept at 1.5 MPa (gauge pressure).

At the time when: 3.5 hours elapsed from the initiation of the polymerization; and the amount of charge of the mixed monomer gas reached 22 kg, the temperature inside the polymerization tank was cooled to room temperature (23° C.) to stop the polymerization. The polymerization tank was purged to lower the pressure inside the polymerization tank to normal pressure (1 atm), thereby obtaining a slurry 2 in the polymerization tank.

The obtained slurry 2 was filtered under suction by a glass filter. By drying the filtered substance at 120° C. for 15 hours, a fluorinated polymer 2 was obtained.

The fluorinated polymer 2 had a composition of TFE units/E units/PFBE units of 57.1/39.5/3.4 in molar ratio.

Further, the melting point of the fluorinated polymer 2 was 231° C., and the MFR of the fluorinated polymer 2 was 13 g/10 min.

### <Production of Pellets 2>

Pellets 2 of the fluorinated polymer 2 were produced according to the method described in the section of <Production of pellets 1> of Ex. 1, except that the above-obtained fluorinated polymer 2 was used; and, in the single-screw extruder, the cylinder temperature was set to 220 to 280° C., and the die temperature was set to 280° C.

### <Production of Tube 2>

A tube 2 having a cross-sectional shape with an inner diameter of 11.1 mm and an outer diameter of 12.7 mm was produced according to the method described in the section of <Production of tube 1> of Ex. 1, except that the above-produced pellets 2 were used; and, in the single-screw extruder, the cylinder temperature was set to 300 to 320° C., and the die temperature was set to 320° C.

### [Ex. 3]

Pellets 3 were prepared using PFA as a fluorinated polymer 3. The fluorinated polymer 3 had a composition of TFE units/perfluoropropyl vinyl ether units of 98.5/1.5 in molar ratio.

Further, the melting point of the fluorinated polymer 3 was 307° C., and the MFR of the fluorinated polymer was 2 g/10 min.

### <Production of Tube 3>

A tube 3 having a cross-sectional shape with an inner diameter of 11.1 mm and an outer diameter of 12.7 mm was produced according to the method described in the section of <Production of tube 1> of Ex. 1, except that the above-prepared pellets 3 were used; in the single-screw extruder, the cylinder temperature was set to 340 to 380° C., and the die temperature was set to 380° C.; and the take-off speed of the tube was adjusted to 0.6 m/min.

### [Ex. 4]

### <Synthesis of Fluorinated Polymer 4>

A polymerization tank of stainless steel having an internal volume of 260 liters and equipped with an agitator and a jacket was degassed and then charged with 165 kg of CF₃CH₂OCF₂CF₂H and 0.64 kg of PFBE (CH₂═CH(CF₂)₄F). While stirring the resulting mixture, the polymerization tank was further charged with 70 kg of hexafluoropropylene (HFP), 23.6 kg of TFE and 0.58 kg of E, and the temperature inside the polymerization tank was raised to 66° C. by the flow of hot water through the jacket.

At this time, the pressure inside the polymerization tank was 1.47 MPa (gauge pressure). After the temperature inside the polymerization tank became stable, 1.48 L of a CF₃CH₂OCF₂CF₂H solution containing 5 mass % of tert-butyl peroxypivalate was introduced into the polymerization tank to initiate polymerization.

During the polymerization, a mixed gas having a composition of TFE/E=54/46 (molar ratio) was introduced into the polymerization tank such that the pressure inside the polymerization tank was kept constant at 1.47 MPa (gauge pressure). In addition, 0.4 L of a CF₃CH₂OCF₂CF₂H solution containing 7.1 mass % of PFBE and 1.3 mass % of itaconic anhydride was introduced into the polymerization tank every time the TFE/E mixed gas introduced during the polymerization was consumed by an amount of 1 kg.

At the time when: 370 minutes elapsed from the initiation of the polymerization; and the amount of introduction of the mixed gas reached 14 kg, the inside of the polymerization tank was cooled to 23° C. to stop the polymerization. A part of the remaining gas was then purged out of the polymerization tank to lower the pressure inside the polymerization tank to atmospheric pressure, thereby obtaining a slurry 4.

The obtained slurry 4 was transferred into a container having an internal volume of 300 L, and the same volume of water as the slurry 4 was introduced into the container. By heating the resulting mixture (20 to 73° C.), the polymerization medium and the remaining unreacted monomer were separated from the polymerization product. The thus-obtained product was dried in an oven of 120° C. to obtain a fluorinated polymer 4 in white powder form.

The fluorinated polymer 4 had a composition of TFE units/E units/HFP units/PFBE units/itaconic anhydride units of 47.5/43.4/8.3/0.6/0.3 in molar ratio.

Further, the melting point of the fluorinated polymer 4 was 191° C., and the MFR of the fluorinated polymer 4 was 2 g/10 min.

### <Production of Pellets 4>

Pellets 4 of the fluorinated polymer 4 were produced according to the method described in the section of <Production of pellets 1> of Ex. 1, except that the above-synthesized fluorinated polymer 4 was used; and, in the single-screw extruder, the cylinder temperature was set to 180 to 240° C., and the die temperature was set to 240° C.

### <Production of Tube 4>

A tube 4 having a cross-sectional shape with an inner diameter of 11.1 mm and an outer diameter of 12.7 mm was produced according to the method described in the section of <Production of tube 1> of Ex. 1, except that the above-produced pellets 4 were used; and, in the single-screw extruder, the cylinder temperature was set to 200 to 240° C., and the die temperature was set to 240° C.

### [Ex. 5]

Prepared were pellets 5 containing polyvinylidene fluoride (PVdF) as a fluorinated polymer 5. The melting point of the fluorinated polymer 5 was 173° C., and the MFR of the fluorinated polymer 5 was 20 g/10 min.

### <Production of Tube 5>

A tube 5 having a cross-sectional shape with an inner diameter of 11.1 mm and an outer diameter of 12.7 mm was produced according to the method described in the section of <Production of tube 1> of Ex. 1, except that: the above-prepared pellets 5 were used; in the single-screw extruder, the cylinder temperature was set to 190 to 230° C., and the die temperature was set to 230° C.; and the take-off speed of the tube was adjusted to 0.6 m/min.

### [Measurement of Physical Properties]

The fluorinated polymer of each Ex. was measured for the following physical properties.

### <Permanent Creep Strain>

The pellets of each Ex. were melt-formed at a temperature (230 to 360° C.) set in consideration of the melting point of the fluorinated polymer in the pellets, to obtain a press sheet of 2 cm thickness. The obtained press sheet was cut to provide three samples with a height of 1.5 cm and a base area of 1 cm².

The permanent creep strain of the sample was then measured in accordance with ASTM D621 by the use of a compression testing machine. More specifically, a load of 140 kgf/cm² was applied to the sample at a temperature of 23° C. for 24 hours, after which the sample was released from pressure and left standing still at a temperature of 23° C. for 24 hours. The dimension of the sample before the application of the load and the dimension of the sample after the standing still for 24 hours were measured. From the dimensions of the sample before and after the load test, the deformation rate (unit: %) was calculated based on the following formula. An arithmetic mean value of the deformation rate calculation results of the three samples was determined and taken as the permanent creep strain.

Deformation rate=100×{(Dimension before load test)−(Dimension after load test)}/Dimension before load test

### <Creep Rate>

The pellets of each Ex. were melt-formed at a temperature (230 to 360° C.) set in consideration of the melting point of the fluorinated polymer in the pellets, to obtain a press sheet of 130 mm×130 mm×2 mm thickness. By punching the obtained press sheet into a ASTM D638 Type 4 dumbbell shape (2 mm thickness), three samples were provided.

The creep rate of the sample was measured in accordance with ASTM D674 by the use of a tensile testing machine. More specifically, the sample was set in the tensile testing machine, and then, a creep tensile test was performed on the sample for 150 hours with the application of a stress of 70 kgf/cm² in a temperature environment of 23° C.±3° C. From the chuck distances before and after the tensile creep test, the deformation rate (unit: %) were calculated based on the following formula. An arithmetic mean value of the deformation rate calculation results of the three samples was determined and taken as the creep rate.

Here, the chuck distance at 100 hours of the tensile creep test was taken as the chuck distance after the test in the following formula.

$$Deformation rate = 100 \times \{ ( Chuck distance before test ) - ( Chuck distance after test ) \} / Chuck distance before test$$

### <Bending Elastic Modulus>

The pellets of each Ex. were melt-formed by an injection forming machine (manufactured by Fanuc Corporation), at a temperature (230 to 360° C.) set in consideration of the melting point of the fluorinated polymer in the pellets, to obtain five test pieces of 127 mm×10 mm×3 mm thickness.

The bending elastic modulus (unit: MPa) of the test piece was then measured in accordance with ASTM D790 by the use of a large-size TENSILON (RTF-1350) under the conditions of a temperature of 23° C., a support span of 40 mm and a speed of 1 mm/min. The bending elastic modulus was calculated from a slope of the measured stress-strain curve in the stress range of 0.3 to 1.2 kgf. An arithmetic mean value of the bending elastic modulus calculation results of the five test pieces was determined and taken as the bending elastic modulus.

### <Water Contact Angle>

The pellets of each Ex. were melt-formed at a temperature (230 to 360° C.) set in consideration of the melting point of the fluorinated polymer in the pellets, to obtain five press sheets (test samples) of 130 mm×130 mm×1 mm thickness.

One drop of pure water was dropped and adhered onto a surface of the test sample, and the angle of contact of the adhered water drop was measured at 23° C. by the use of a contact angle meter (manufactured by Kyowa Interface Science Co., Ltd.). Here, the 0/2 method was used for the determination of the contact angle.

An arithmetic mean value of the contact angle measurement results of the five test samples was determined and taken as the water contact angle.

### [Evaluations]

The following evaluation tests were performed on the tube of each Ex.

### <Joint Connectivity>

The tube was cut by a tube cutter such that cross sections at both ends were parallel to each other, and then, the cut tube was set in a tube holder of a lever-type press-fit jig. An attachment for flaring was put onto the press-fit jig, and flaring was carried out by a cold flaring method to radially expand the tube. After the flaring, the tube was removed by unlocking a clamp of the press-fit jig. The removed tube was connected to a joint. Subsequently, the connection part between the tube and the joint was tightened with a nut.

Next, the tube to which the joint was connected was connected to an air compressor by a commercially available rubber tube. The connection face between the rubber tube and the resinous tube was reinforced with a plastic tape and a fastener so as not to cause air leakage. The tube to which the joint was connected was sunk in a water tank, and air was fed at a pressure of 1 MPa from the air compressor. In this state, the occurrence or non-occurrence of air leakage from the connection face between the joint and the tube was observed for 10 minutes.

Based on the ease of flaring of the tube, the time required for connection of the tube to the joint and the test result of liquid leakage at the connection part between the tube and the joint, the connectivity of the tube to the joint was evaluated according to the following criteria. Here, five tubes for each Ex. were prepared and used for evaluation.

### (Criteria for Evaluation of Joint Connectivity)

4: The average total time required for flaring of the tube and connection of the tube to the joint was 10 seconds or less, and it was easy to connect the tube to the joint. Furthermore, the number of the tubes where liquid leakage was observed was 0.

3: Although the average total time required for flaring of the tube and connection of the tube to the joint was more than 10 seconds and less than or equal to 20 seconds, it was easy to connect the tube to the joint; and the number of the tubes where liquid leakage was observed was 0 to 1.

2: Although the average total time required for flaring of the tube and connection of the tube to the joint was over 20 seconds, it was possible to connect the tube to the joint; and the number of the tubes where liquid leakage was observed was 0 to 2.

1: It was impossible to connect the tube to the joint, or it was necessary to conduct heating for connection of the tube to the joint; and the number of the tubes where liquid leakage was observed was 3 or more.

### <Cleanability>

By placing 30 g of the pellets of each Ex. and 100 of ultrapure in a double-stoppered bottle container, an elution test was conducted for 7 days in a thermostatic bath of 85° C. After that, the amount of TOC (total organic carbon) in the eluate was measured by a TOC meter (TOC-Vwp, manufactured by SHIMADZU CORPORATION) using a wet oxidation method as its measurement principle in accordance with SEMI F57. The measured value was taken as the TOC elution before cleaning.

Further, 30 g of the pellets of each Ex. (pellets before elution test) and 100 g of ultrapure water were placed in a double-stoppered bottle container, stirred by a glass rod and left standing still for 2 minutes, after which the water was thrown away. This operation was repeated 10 times to obtain the cleaned pellets. An elution test using the cleaned pellets was conducted in the same manner as the above elution test, except that the cleaned pellets were used. The TOC elution from the cleaned pellets was measured in the same manner as the above measurement of the TOC elution from the pellets before cleaning.

Based on the TOC elutions before and after the cleaning, the cleanability was evaluated according to the following criteria.

Although the cleanability of the pellets was herein evaluated, the evaluation results of the cleanability of the pellets are the same in tendency as those of the tube because the pellets and the tube are the same in that they are formed products.

### (Evaluation Criteria for Cleanability)

O: A decrease in the TOC elution of 10 mass % or more before and after the cleaning was observed.

X: A decrease in the TOC elution of less than 10 mass % before and after the cleaning was observed.

Here, “-” in the table below indicates no evaluation test performed.

TABLE 1
Table 1

| | | Ex. 1 | Ex. 2 | Ex. 3 | Ex. 4 | Ex. 5 |
|---|---|---|---|---|---|---|
| Fluorinated polymer | | 1 | 2 | 3 | 4 | 5 |
| Physical | Permanent | 7.1 | 4.8 | 1.4 | 1.6 | 0.1 |
| properties | creep | | | | | |
| | strain (%) | | | | | |
| | Creep | 1.35 | 20.2 | 2.62 | 1.28 | 0.5 |
| | rate (%) | | | | | |
| | Bending | 748 | 1073 | 590 | 750 | 1800 |
| | elastic | | | | | |
| | modulus | | | | | |
| | (Mpa) | | | | | |
| | Contact | 104.1 | 101.2 | 112.1 | 101.2 | 88.8 |
| | angle | | | | | |
| | (degrees) | | | | | |
| Evaluations | Joint | 4 | 3 | 2 | 2 | 1 |
| | connec- | | | | | |
| | tivity | | | | | |
| | Clean- | ◯ | ◯ | X | — | — |
| | ability | | | | | |

As shown in Table 1, it was confirmed that the tube produced using the fluorinated polymer, when the formed product of the fluorinated polymer satisfies the requirement A, has excellent joint connectivity and excellent cleanability (see Ex. 1 and Ex. 2).

This application is a continuation of PCT Application No. PCT/JP2023/046905, filed on Dec. 27, 2023, which is based upon and claims the benefit of priority from Japanese Patent Application No. 2022-212110 filed on Dec. 28, 2022. The contents of those applications are incorporated herein by reference in their entireties.

What is claimed is:

1. A tube for semiconductor manufacturing equipment, comprising a fluorinated polymer,
wherein the fluorinated polymer satisfies the following requirement A:
(requirement A)
a permanent creep strain of the fluorinated polymer is 4.5% or more;
a creep rate of the fluorinated polymer as determined by a tensile creep test is 2.60% or lower;
a bending elastic modulus of the fluorinated polymer is 1100 MPa or lower; and
a water contact angle of the fluorinated polymer is 112.0 degrees or smaller.

2. The tube according to claim 1, wherein the fluorinated polymer comprises units based on tetrafluoroethylene.

3. The tube according to claim 2, wherein the fluorinated polymer further comprises units based on at least one monomer selected from the group consisting of ethylene, propylene, a fluoroalkyl ethylene and a perfluoro (alkyl vinyl ether).

4. The tube according to claim 2, wherein the fluorinated polymer further comprises units based on at least one monomer selected from the group consisting of ethylene and a fluoroalkyl ethylene.

5. The tube according to claim 1, wherein the tube is a tube for transporting a chemical liquid for semiconductors in semiconductor manufacturing equipment or a tube for transporting a gas in semiconductor manufacturing equipment.

6. The tube according to claim 1, wherein the water contact angle is 90 degrees or larger.
